(19) United States
(12) Patent Application Publication
(10) Pub. No.: US 2015/0179678 A1
(43) Pub. Date: Jun. 25, 2015

(54) LIQUID CRYSTAL DISPLAY ARRAY SUBSTRATE, SOURCE DRIVING CIRCUIT AND BROKEN LINE REPAIRING METHOD

(71) Applicant: SHENZHEN CHINA STAR OPTOELECTRONICS TECHNOLOGY CO., LTD., Shenzhen, Guangdong (CN)

(72) Inventor: Xiangyang Xu, Shenzhen (CN)

(73) Assignee: SHENZHEN CHINA STAR OPTOELECTRONICS TECHNOLOGY CO., LTD., Shenzhen, Guangdong (CN)

(21) Appl. No.: 14/240,386

(22) PCT Filed: Jan. 17, 2014
(86) PCT No.: PCT/CN2014/070837

§ 371 Date: Jul. 30, 2014

(30) Foreign Application Priority Data
Dec. 25, 2013 (CN) 201310729101.8

(51) Int. Cl. H01L 27/12; G09G 3/36; G02F 1/1362

(52) U.S. Cl. CPC H01L 27/1244; G02F 1/136259; G09G 3/3648; G02F 2001/136272; G09G 2330/08; G09G 2330/12

(57) ABSTRACT

The present disclosure disclosed an array substrate of a liquid crystal display, a source driving circuit, and a method for repairing the broken line. The method includes: gate lines, arranged in parallel on a base for transmitting scan signals to a display panel; data lines, arranged on the base in a manner that the data lines are on different layers from that in which the gate lines are located, and are oriented vertically to the gate lines, for transmitting source driving signals to the display panel; and two or more repairing lines, arranged on the base and including a first group of terminals and a second group of terminals, wherein the first group of terminals is pending; the second group of terminals is connected with the output end of a source driving circuit. The design of the present disclosure is simple, and thus the method for repairing the broken line is convenient so as to improve the productivity.

### FIELD OF THE INVENTION

The present disclosure relates to the technical field of liquid crystal display, and particularly, to a liquid crystal display array substrate, a source driving circuit and a method of repairing broken line in the liquid crystal display array substrate.

### BACKGROUND OF THE INVENTION

In current flat-panel display technology, a liquid crystal display (LCD), in particular, a thin film transistor-liquid crystal display (TFT-LCD), is the most mature technology. The liquid crystal display includes array substrates designed in a matrix form and a driving circuit for driving these array substrates, and deflection of liquid crystal molecules is realized through variation of an electric field of a liquid crystal cell, so that a display effect is achieved.

With the development of semiconductor technologies, the size of a TFT device becomes smaller and smaller, and the resolution of the LCD becomes higher and higher, so that narrower and narrower metal wires are required. For the conventional process level, the risks directly brought by narrowing the wires are the failures of short-circuit and open-circuit. In the prior art, the rate of intercepting short-circuit/open-circuit failure of an array is greatly related to the structural design of the LCD. When two ends of each of a Gate line and a Data line are in an open-circuit state, the possibility of detecting the short-circuit/open-circuit nearly reaches 100%. However, some weak broken lines would be erroneously passed to a Cell box processing phase and a Module processing phase.

For decreasing the ratio of this part of broken lines erroneously passed, some repairing lines are generally provided in peripheral wires of a panel in an Array manufacturing process phase. The traditional structure for repairing line includes a data input end repairing line, a data output end repairing line, and a PCB OP (compensating) line. The repairing lines shown in FIG. 1 can repair 4 vertical broken lines. However, since the repairing lines are relatively complex, a large space will be occupied. Moreover, the method of repairing the lines is also relatively complex.

Accordingly, there is a need for providing a simple design for repairing vertical broken lines so as to improve the repairing efficiency.

### SUMMARY OF THE INVENTION

To solve the above-mentioned technical problems, the present disclosure provides an array substrate of a liquid crystal display, including:

gate lines, arranged in parallel on a base for transmitting scan signals to a display panel;

data lines, arranged on the base in a manner that the data lines are on a different layer from that in which the gate lines are located, and are oriented vertically to the gate lines, for transmitting source driving signals to the display panel; and

two or more repairing lines, arranged on the base and including a first group of terminals and a second group of terminals, wherein the first group of terminals is pending, so that when a broken point of a certain one of the data lines is detected, one terminal of the first group of terminals can be connected with the output end of the data line; the second group of terminals is connected with an output end of said source driving circuit, and when the source driving circuit receives an open circuit repairing control signal, a driving signal which is the same as that at an input end of said one of the data lines with the broken point is output to the second group of terminals, enabling the repairing lines as a whole can close the circuit with the broken point.

According to an embodiment of the present disclosure, the repairing lines and the data lines are arranged on the same layer of the base.

According to an embodiment of the present disclosure, the repairing lines are arranged along the periphery of the base to form approximate “L” shapes.

According to an embodiment of the present disclosure, the open-circuit repairing control signal includes information indicating which data line contains the broken point.

According to an embodiment of the present disclosure, the first group of terminals of each repairing line is arranged on a lower part of the base near the output ends of the data lines, and the second group of terminals of each repairing line is arranged on an upper part of the base near the source driving circuit.

According to an embodiment of the present disclosure, the repairing lines are symmetrically arranged on the periphery of the base in pairs. The second group of terminals of the repairing line arranged on the left side of the base is connected with the output end of the respective source driving circuit on the left side, and the second group of terminals of the repairing line arranged on the right side of the base is connected with the output end of the respective source driving circuit on the right side.

According to one aspect of the present disclosure, a source driving circuit is also provided, including:

a grayscale voltage input end, arranged on one side of the circuit for receiving a grayscale voltage input signal;

a driving voltage output end, arranged on the other side of the circuit for outputting source driving voltage signals suitable for driving a liquid crystal display panel;

a repairing control input end, configured to input a repairing control signal to the source driving circuit, wherein the repairing control signal indicates position information of a broken point on a data line in an array substrate and number of a repairing line with one end being connected with the data line; and

repairing output ends, connected with a second group of terminals of the repairing line of the array substrate, for output a driving signal which is the same as that at the input end of the data line with the broken point to the second group of terminals of the corresponding repairing line based on the position information and the number of the repairing line in the repairing control signal.

According to an embodiment of the present disclosure, the source driving circuit further includes a Mini LVDS/TTL input end.

According to one aspect of the present disclosure, a method for repairing a broken line in data lines of a liquid crystal display is provided, including the following steps:

detecting and determining which data line contains a broken point;

bonding one or more of a first group of terminals of a repairing line with the output end of the data line with the broken point;

inputting, in a module programming phase, position information of the data line with the broken point and number of the bonded repairing line to a source driving circuit through a repairing control input end; and

outputting, when the source driving circuit outputs a driving voltage signal to the data line, a driving signal which is the same as that at the input end of the data line with the broken point to a second group of terminals of the repairing line with the corresponding number.

By adopting the technical solution of the present disclosure, there is no need for designing a fan-out area repairing line at the input end of the data line, and thus the design of the repairing line and the repairing method are simplified, and the repairing efficiency is improved.

Other features and advantages of the present disclosure will be illustrated in the following description, and are partially obvious from the description or understood through implementing the present disclosure. The objectives and other advantages of the present disclosure may be realized and obtained through the structures specified in the description, claims and accompanying drawings.

### BRIEF DESCRIPTION OF THE DRAWINGS

The accompanying drawings are provided for a further understanding of the present disclosure, constitute a part of the description, and are used for interpreting the present disclosure together with the embodiments of the present disclosure, rather than limiting the present disclosure. In the accompanying drawings:

FIG. 1 shows a layout diagram of a design line for repairing a broken line in the prior art;

FIG. 2 shows a layout diagram of a design for repairing a broken line according to an embodiment of the present disclosure;

FIG. 3 shows a layout diagram of input/output at the side of a source driving circuit (Source IC) in the prior art;

FIG. 4 shows a layout diagram of input/output at the side of a source driving circuit (Source IC) matched with the design line for repairing a broken line of the present disclosure; and

FIG. 5 is a flow diagram of a method for repairing broken line of a display panel according to an embodiment of the present disclosure.

### DETAILED DESCRIPTION OF THE EMBODIMENTS

The embodiments of the present disclosure will be illustrated in detail in conjunction with the accompanying drawings and examples, and thus how to use technical means to solve the technical problems and the implementation process of achieving the technical effects may be fully understood and accordingly implemented. It should be noted that as long as conflicts are avoided, all embodiments in the present disclosure and all features in all the embodiments may be combined together, and the formed technical solutions are all within the protection scope of the present disclosure.

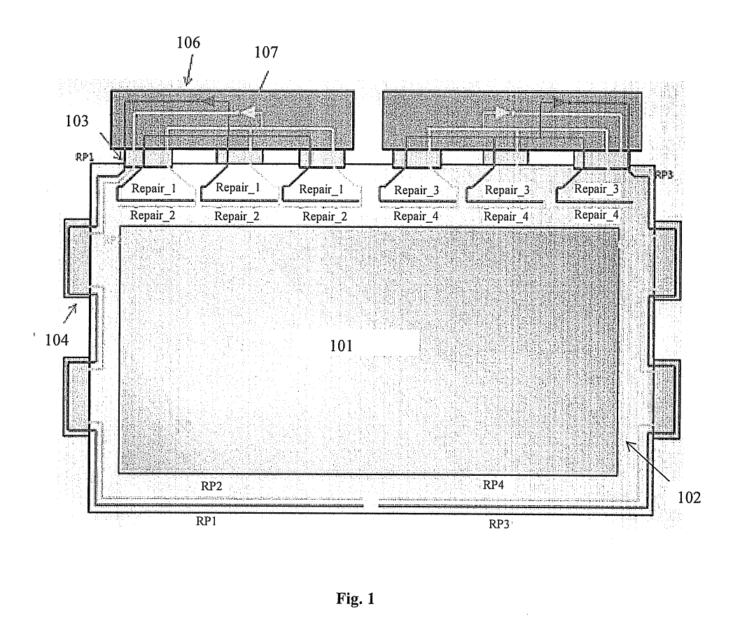

FIG. 1 shows a layout of a peripheral circuit of a traditional array substrate, and shows a repairing line design of four repaired broken lines (RP1, RP2, RP3 and RP4). In the layout shown in FIG. 1, at most four broken lines including two in a left area and two in a right area may be repaired. The repairing method for such a design includes following steps:

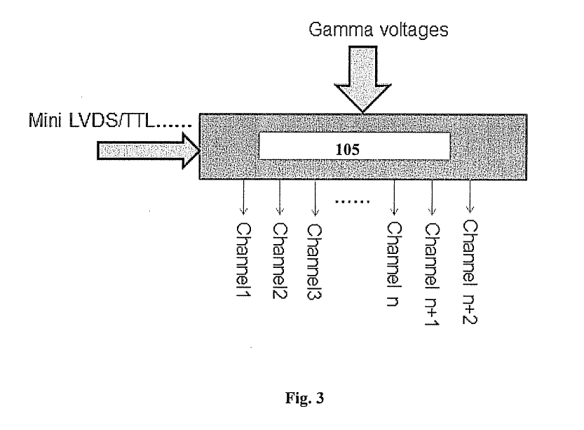

if data line n in the left area of the array substrate has a defect of an open-circuit, welding the data output end and the data input end of the data line with two ends of one single repairing line respectively. If the welding operation of one end fails, the repairing operation can not be completed. Moreover, because a driving signal of the repaired data line should be transmitted to the output end of the data line through a welding point and the whole repairing line, the signal is attenuated greatly, and thus an OP amplifying circuit 107 is generally added on a printed circuit board (PCB) 106. A source driving circuit corresponding to the repairing line is shown in FIG. 3.

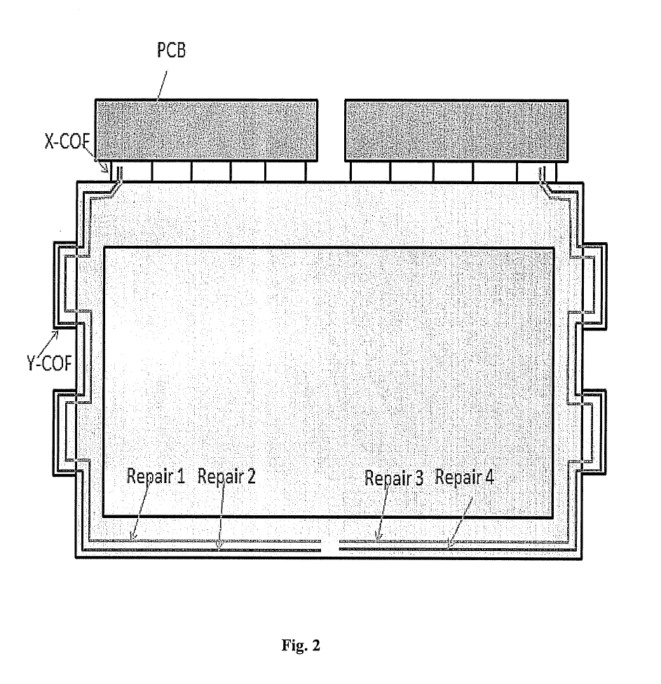

It can be obviously seen that the operating steps of the above-mentioned broken line repairing method refer to two times of welding operation, so the method is relatively time-consuming and unreliable. Moreover, the design of the repairing line is relatively complex. Accordingly, to simplify the repairing line and the repairing method and improve the success rate of repairing, the present disclosure provides a design line for repairing broken lines shown in FIG. 2. Although a design line for repairing a vertical broken line is shown, the present disclosure is not limited to this, and any circuit on the array substrate may be repaired based on the concept of the present disclosure.

FIG. 2 shows a display panel 101, an array substrate 102, an X-directional chip on film (COF) module 103, a Y-directional COF module 104, a source driving circuit (Source IC) 105 and the like. Gate Lines and Data Lines are arranged on the array substrate, wherein the gate lines are arranged in parallel on a base for transmitting scan signals to the display panel. The data lines are arranged on the base in a manner that the data lines are on different layers from the gate lines and are vertical to the gate lines, for transmitting source driving signals to the display panel.

Moreover, two or more repairing lines (RP1, RP2, RP3 and RP4) disposed on the periphery of the panel are arranged on the base and include a first group of terminals and a second group of terminals, wherein the first group of terminals is pending, so that when a broken point of a certain one of the data lines is detected, one terminal of the first group of terminals can be connected with the output end of the data line. The second group of terminals of the repairing line is connected with the output end of a source driving circuit, and when the source driving circuit receives an open circuit repairing control signal, a driving signal which is the same as that at the input end of the data line with the broken point is output to the second group of terminals, so that the repairing line as a whole can close the circuit with the broken point.

According to an embodiment of the present disclosure, the repairing lines (RP1, RP2, RP3 and RP4) and the data lines may be arranged on the same layer of the base, so that the first group of idle terminals can be bonded with the output end of the data line. If the repairing lines and the data lines are not on the same layer, a via hole through which the repairing line may be arrived is formed in the layer where the data line is arranged. The present disclosure is not limited to this, and any circuit layout facilitating to bond the pending terminals of the repairing line with the output end of the data line can be conceived by those skilled in the art.

Preferably, the first group of terminals of the repairing lines (RP1, RP2, RP3 and RP4) is arranged on the lower part of the base and close to the output ends of the data lines, and the second group of terminals of the repairing lines is arranged on the upper part of the base and close to the source driving circuits. The repairing lines are preferably symmetrically arranged on the periphery of the base in pair, the second group of terminals of the repairing line arranged on the left side of the base is correspondingly connected with the output end of the source driving circuit on the left side, and the second group of terminals of the repairing line arranged on the right side of the base is correspondingly connected with the output end of the source driving circuit on the right side.

More specifically, as shown in FIG. 2, each repairing line may be disposed to pass through the Y-directional COF module. Although 4 repairing lines shown herein are symmetrically arranged on two sides of the panel and extend to the center of the bottom to form approximate “L” shapes, the present disclosure is not limited to this, and the number of the repairing lines may be more such as 6 or less such as 2 according to actual needs.

Obviously, in FIG. 2, there is no need for designing a repairing line of the input ends of the data lines, and repairing signals are directly transmitted from pins of pad areas of the data lines to the output ends of the data lines along the periphery of the panel. When data line n is open-circuit, only the output end of data line n is welded or bonded in any manner known in the art with one end of the repairing line, for example the first end.

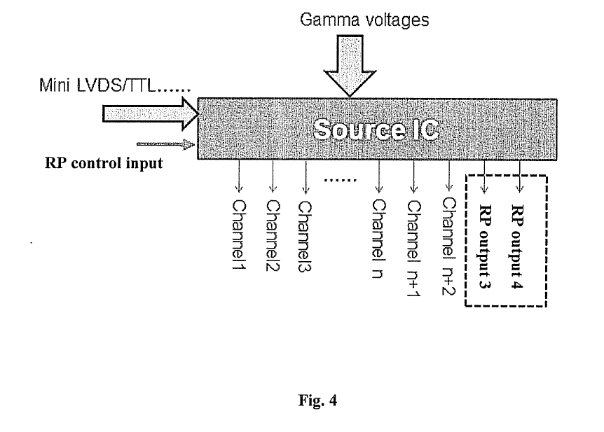

FIG. 4 shows a layout diagram of input/output at the side of a source driving circuit (Source IC) matched with the design line for repairing the broken line in the present disclosure. The source driving circuit shown in the diagram also includes a grayscale voltage (Gamma voltage) input end, driving voltage output ends (channel 1, channel 2 . . . channel n, channel n+1 etc.), a repairing control input end and repairing output ends (such as a repairing output 3 and a repairing output 4 corresponding to repairing lines RP1 and RP2 respectively) beside other components. Moreover, the source driving circuit also includes a Mini LVDS/TTL input end.

The grayscale voltage input end is arranged on one side of the source driving circuit for receiving a grayscale voltage input signal. The driving voltage output ends are arranged on the other side of the circuit for outputting source driving voltage signals suitable for driving a liquid crystal display panel.

The repairing control input end is configured to input a repairing control signal to the source driving circuit (Source IC). The repairing control signal indicates position information of a broken point on a data line and number of a repairing line with one end being connected with the data line. The signal is written into a memory after the broken line is repaired. The Source IC controls the output of the repairing output ends through broken line coordinates provided by the repairing control signal.

The repairing output ends are connected with a second group of terminals of the repairing line for outputting a driving signal which is the same as that at the input end of the data line with the broken point to the second group of terminals of the corresponding repairing line based on the position information and the number of the repairing line in the repairing control signal as obtained above.

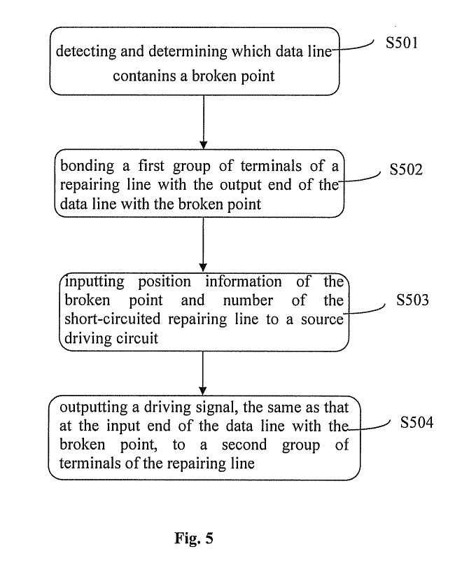

As shown in FIG. 5, a method for repairing a broken line of a data line in a liquid crystal display is provided, including the following steps:

S501, detecting and determining which data line contains a broken point;

S502, bonding one or more of a first group of terminals of a repairing line with the output end of the data line with the broken point;

S503, inputting, in a module programming phase, position information of the data line with the broken point and number of the bonded repairing line to a source driving circuit through a repairing control input end; and

S504, outputting, when the source driving circuit outputs a driving voltage signal to the data line, a driving signal which is the same as that at the input end of the data line with the broken point to a second group of terminals of the repairing line of the corresponding number.

Although the embodiments are described as above, the foregoing are merely the embodiments for facilitating the understanding of the present disclosure, rather than limiting the present disclosure. Any changes or alternatives conceived by the skilled ones in the art after reading the content disclosed herein will fall within the scope of the present disclosure. Accordingly, the scope of the present disclosure will be defined in the accompanying claims.

What is claimed is:

1. An array substrate of a liquid crystal display, including:
gate lines, arranged in parallel on a base for transmitting scan signals to a display panel;
data lines, arranged on the base in a manner that the data lines are on a different layer from that in which the gate lines are located, and are oriented vertically to the gate lines, for transmitting source driving signals to the display panel; and
two or more repairing lines, arranged on the base and including a first group of terminals and a second group of terminals,
wherein the first group of terminals is pending, so that when a broken point of one of the data lines is detected, one terminal of the first group of terminals can be connected with an output end of said one of the data lines;
the second group of terminals is connected with an output end of a source driving circuit, so that when the source driving circuit receives an open circuit repairing control signal, a driving signal which is the same as that at an input end of said one of the data lines with the broken point is output to the second group of terminals, enabling the repairing lines as a whole can close the circuit with the broken point.

2. The array substrate as recited in claim 1, wherein the repairing lines and the data lines are arranged on the same layer of the base.

3. The array substrate as recited in claim 1, wherein the repairing lines are arranged along the periphery of the base to form an approximate “L” shape.

4. The array substrate as recited in claim 3, wherein the open-circuit repairing control signal includes information indicating which data line contains the broken point.

5. The array substrate as recited in claim 3, wherein the first group of terminals of the repairing line is arranged on a lower part of the base near the output ends of the data lines, and the second group of terminals of the repairing line is arranged on an upper part of the base near the source driving circuit.

6. The array substrate as recited in claim 1, wherein the repairing lines are symmetrically arranged on the periphery of the base in pairs, in which the second group of terminals of the repairing line arranged on the left side of the base is connected with the output end of the respective source driving circuit on the left side, and the second group of terminals of the repairing line arranged on the right side of the base is connected with the output end of the respective source driving circuit on the right side.

7. The array substrate as recited in claim 2, wherein the repairing lines are arranged along the periphery of the base to form an approximate “L” shape.

8. A source driving circuit, including:
a grayscale voltage input end, arranged on one side of the circuit for receiving a grayscale voltage input signal;
a driving voltage output end, arranged on the other side of the circuit for outputting source driving voltage signals suitable for driving a liquid crystal display panel;
a repairing control input end, configured to input a repairing control signal to the source driving circuit, wherein the repairing control signal indicates position information of a broken point on a data line in an array substrate and number of a repairing line with one end being connected with the data line; and
repairing output ends, connected with a second group of terminals of the repairing line of the array substrate, for outputting a driving signal which is the same as that at the input end of the data line with the broken point to the second group of terminals of the corresponding repairing line based on the position information and the number of the repairing line in the repairing control signal.

9. The source driving circuit as recited in claim 8, wherein the source driving circuit further includes a Mini LVDS/TTL input end.

10. A method for repairing a broken line in data lines of a liquid crystal display, including steps of:
detecting and determining which data line contains a broken point;
bonding one or more of a first group of terminals of a repairing line with the output end of the data line with the broken point;
inputting, in a module programming phase, position information of the data line with the broken point and number of the bonded repairing line to a source driving circuit through a repairing control input end; and
outputting, when the source driving circuit outputs a driving voltage signal to the data line, a driving signal which is the same as that at the input end of the data line with the broken point to a second group of terminals of the repairing line with the corresponding number.
